(19) United States
(12) Patent Application Publication
(10) Pub. No.: US 2025/0107055 A1
(43) Pub. Date: Mar. 27, 2025

(54) ABSORBER FOR PRINTED CIRCUIT BOARD ASSEMBLY

(71) Applicant: Cisco Technology, Inc., San Jose, CA (US)

(72) Inventors: Wenbin Ma, Shanghai (CN); Shiqing He, Shanghai (CN); Yong Wu, Shanghai (CN); Joel Richard Goergen, Soulsbyville, CA (US); Mike Sapozhnikov, San Jose, CA (US); Xinghai Tang, Shanghai (CN); Dewen Xu, Shanghai (CN); Haiying Zhu, Shanghai (CN)

(21) Appl. No.: 18/390,757

(22) Filed: Dec. 20, 2023

Related U.S. Application Data
(60) Provisional application No. 63/584,584, filed on Sep. 22, 2023.

(51) Int. Cl. H05K 9/00; H05K 1/02

(52) U.S. Cl. CPC H05K 9/0035; H05K 1/023; H05K 2201/0707; H05K 2201/09227; H05K 2201/10371

(57) ABSTRACT

Presented herein is a printed circuit board (PCB) assembly with an absorber having a perforated structure. The absorber is positioned between a trace of a PCB and a connector that couples the PCB to an enclosure. The absorber includes a perforated structure to maintain an integrity of a signal propagated along the trace, while improving electromagnetic interference and/or electromagnetic compatibility properties.

### PRIORITY CLAIM

This application claims priority to U.S. Provisional Application No. 63/584,584, filed Sep. 22, 2023, the entirety of which is incorporated herein by reference.

### TECHNICAL FIELD

The present disclosure relates to an absorber for a printed circuit board (PCB) assembly.

### BACKGROUND

A printed circuit board (PCB) is used for processing and transmitting signals. A PCB may be coupled to an enclosure (e.g., a cage) to block unwanted effects caused by electromagnetic energy, such as electrical energy, from an external source. For example, the enclosure may block interference of transmitted signals. Unfortunately, at higher signal data rates, signals propagated along the PCB can be emitted out of the enclosure, such as via a panel (e.g., a front panel) of the enclosure and/or from a connector that couples the PCB to the enclosure. Thus, signal integrity may be reduced.

### BRIEF DESCRIPTION OF THE DRAWINGS

FIG. 1A shows a perspective view of a printed circuit board (PCB) assembly with an absorber having a perforated structure, in accordance with embodiments of the present disclosure.

FIG. 1B shows a side view of a PCB assembly with an absorber having a perforated structure, in accordance with embodiments of the present disclosure.

FIG. 1C shows a side view of another PCB assembly with an absorber having a perforated structure, in accordance with embodiments of the present disclosure.

FIG. 2 shows a top perspective view of a PCB assembly with an absorber having a perforated structure, in accordance with embodiments of the present disclosure.

FIG. 3 shows a top perspective view of another PCB assembly with an absorber having a perforated structure, in accordance with embodiments of the present disclosure.

FIGS. 4-7 show top views of a PCB assembly with an absorber having a perforated structure, in accordance with embodiments of the present disclosure.

FIG. 8 shows a schematic diagram of a PCB assembly with an absorber having a perforated structure, in accordance with embodiments of the present disclosure.

FIG. 9 shows a flowchart of a method of manufacturing a PCB assembly that includes an absorber having a perforated structure, in accordance with embodiments of the present disclosure.

### DESCRIPTION OF EXAMPLE EMBODIMENTS

### Overview

The techniques presented herein improve signal propagation for a printed circuit board (PCB), such as for higher data rates applications. In some aspects, the techniques described herein relate to an apparatus, including: a layer of a printed circuit board (PCB); a trace routed along the layer and configured to transmit a signal; and an absorber positioned over the trace, wherein the absorber is formed of material that absorbs electromagnetic emissions from the trace, the absorber comprises a plurality of openings, and an opening of the plurality of openings overlaps with the trace.

Presented herein are techniques that address electromagnetic interference and electromagnetic compatibility issues, while maintaining signal integrity associated with operation of a printed circuit board (PCB), such as for higher data rates. Specifically, a PCB is coupled to an enclosure or cage, which is configured to block or limit external electromagnetic energy from affecting signals associated with (e.g., generated by, transmitted along) the PCB. That is, the enclosure may electrically isolate the signals of the PCB. The PCB may include a trace routed along a layer (e.g., an external layer) of the PCB, as well as connectors to couple the PCB, such as the layer along which the trace is routed, to the enclosure. During operation of the PCB, the trace may propagate a signal.

Unfortunately, the signal propagated along the trace may be emitted off the trace and out of the enclosure. As an example, the enclosure may include a panel that exposes the trace to an external environment and causes potential emission of the signal from the trace to the external environment. As another example, the signal may be emitted to a connector coupling the PCB to the enclosure, and the connector may emit the signal to the external environment. Consequently, signal integrity is reduced and/or there may still be electromagnetic interference (EMI) of the signal.

Thus, blocking emission of the signal off the trace may improve signal integrity and therefore operation of the PCB. For this reason, an absorber (also called an “absorber member”) may be positioned over the trace. The absorber may absorb electromagnetic radiation/emissions to block emission of the signal off the trace and facilitate propagation of the signal along the trace. The absorber may include a perforated structure to maintain an integrity of the signal propagated along the trace. As an example, the perforated structure of the absorber may reduce a variation of environmental properties (e.g., impedance) at the trace. For instance, the absorber may extend along a first portion of the trace, whereas a second portion of the trace may be offset from the absorber and therefore exposed to air. However, the perforated structure may increase exposure of the first portion of the trace to air. Thus, each of the first portion and the second portion of the trace may be at least partially exposed to air. The reduced variation of environmental properties may cause the trace to propagate along a more homogenous environment to improve signal integrity.

### Example Embodiments

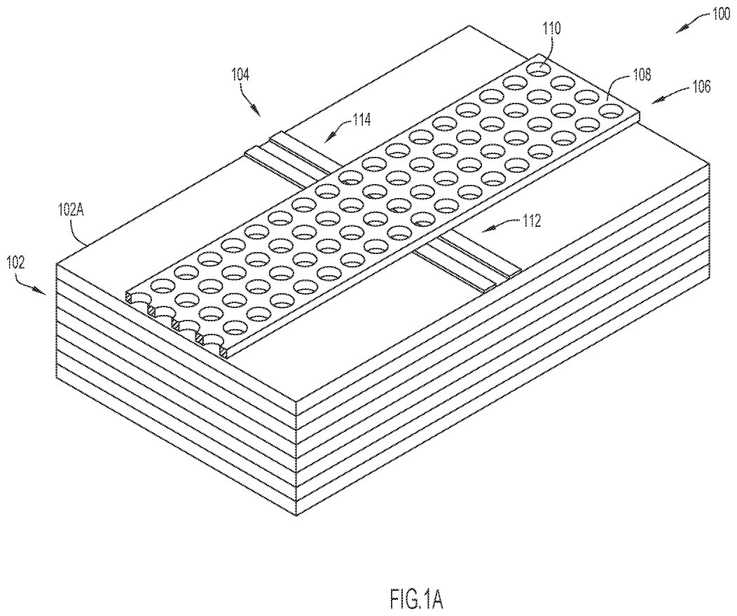

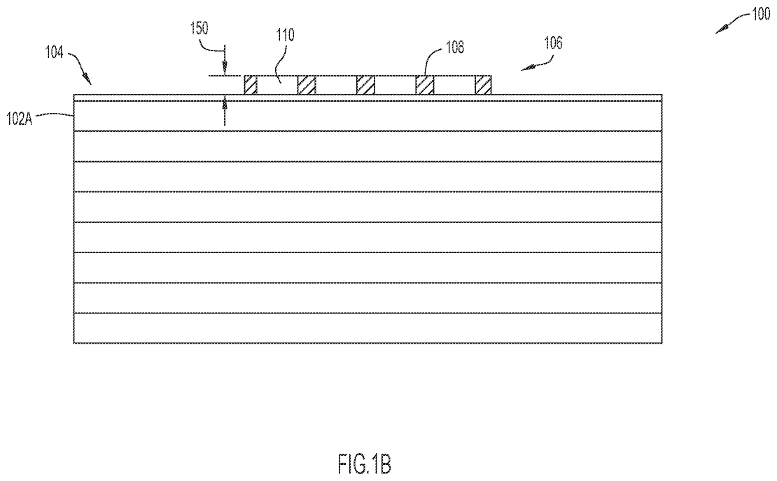

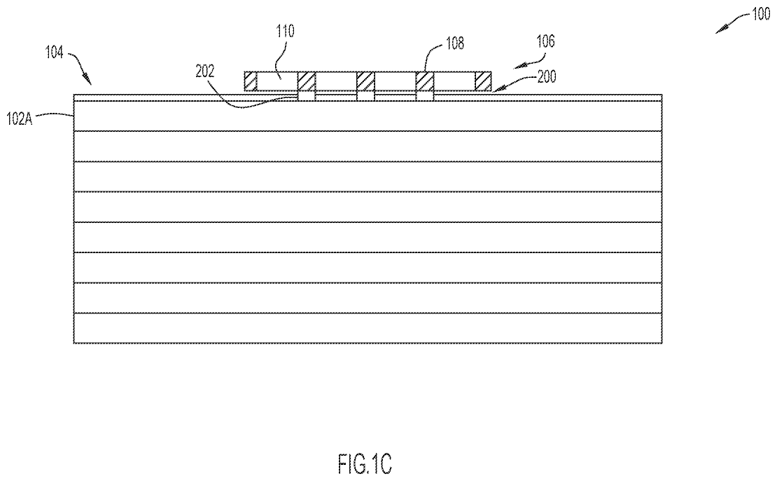

FIG. 1A shows a perspective view of an embodiment of a PCB assembly 100. The PCB assembly 100 may include multiple layers 102 that may include different electronic components that are electrically coupled to one another. Traces 104 may be routed along a layer 102A (e.g., along a dielectric glass resin material), such as an outer layer, for electrically coupling components positioned on the layer 102A. For example, one end of a trace 104 may be electrically coupled to an electronic component positioned on the layer 102A, and another end of the trace 104 may be electrically coupled to a via extending through the layer 102A (e.g., to another of the layers 102 to electrically couple to another electric component), thereby electrically coupling the electronic component and the via to one another. As an example, the traces 104 may each be coupled to a respective via using a dog-bone fanout or other configuration. Each of the traces 104 may be configured to propagate respective signals. In some embodiments, the traces 104 may be differential traces configured to propagate corresponding signals (e.g., a positive signal, a negative signal). In additional or alternative embodiments, the traces 104 may be single ended traces that propagate separate, unrelated signals. For example, the traces 104 may be high-speed microstrip traces configured to transmit signals at a high rates.

The PCB assembly 100 may include an enclosure or cage (not shown) surrounding or adjacent to the layer 102A to block unwanted effects from external electromagnetic activities. That is, the enclosure may block electrical interference that may otherwise affect integrity of the signals transmitted along the layers 102, especially for belly-to-belly configurations (e.g., with a dog-bone fanout configuration on an external layer) in which signals are propagated along outer layers (e.g., outer surfaces) positioned at opposite ends of the PCB assembly 100. However, the enclosure may not adequately maintain desirable integrity of signals transmitted along the traces 104. For instance, the enclosure may include a panel or wall (e.g., an input/output interface, such as a small form-factor pluggable, quad small form-factor pluggable, quad small form pluggable double density, octal small form factor pluggable) that exposes a significant portion of the traces 104 to an external or ambient environment (e.g., to enable connection of separate components to the layer 102A, such as to the traces 104). Additionally or alternatively, a connector may be used to couple the layer 102A to the enclosure, and the connector may be positioned adjacent to the traces 104. Thus, a signal propagating along the traces 104 may be susceptible to emission to the connector. As a result, a portion of the signals transmitted along the traces 104 may be emitted out of the enclosure to reduce signal integrity.

For this reason, an absorber 106 is positioned over the traces 104 to cover the traces 104. The absorber 106 is configured to absorb electromagnetic radiation/emissions from the traces 104 to block potential signal emission off the traces 104 for achieving desirable electromagnetic compatibility (EMC) and/or EMI performance and maintaining signal integrity. For instance, the absorber 106 may include a sheet with a base 108 composed of a material with high resistance and high permeability, such as a metal (e.g., aluminum, copper, tin, ferrite powder, gold fabric, nickel), a polymer (e.g., a form of polyester), a nitrile, a resin (e.g., epoxy powder), another suitable material, or any combination thereof. The base 108 may extend along the layer 102A to cover each of the traces 104. Although a rectangular base 108 extending perpendicularly across the traces 104 is shown in the illustrated embodiment, a base 108 having any other suitable shape and/or extending in any suitable manner/direction relative to the traces 104 may be implemented in additional or alternative embodiments. In some embodiments, multiple absorbers 106 may be used, such as respective absorbers 106 that separately cover the traces 104.

Additionally, openings or holes 110 may be formed through the base 108 to provide a perforated structure of the absorber 106. The openings 110 may further help achieve desirable signal integrity related to the traces 104. By way of example, the absorber 106 may extend over a first portion 112 of the traces 104, whereas a second portion 114 of the traces 104 may remain exposed (e.g., to air). Thus, the different portions 112, 114 of the traces 104 may be exposed to or surrounded by different environments (e.g., absorber 106 elements or air elements) and therefore different environmental properties. However, substantial changes in certain environmental properties, such as a dielectric constant, a permeability value, and/or an impedance, may affect signal integrity. That is, discontinuities between environments may degrade a signal. As such, the absorber 106 may be structured to reduce or limit significant changes in such environmental properties, such as between the first portion 112 and the second portion 114 of the traces 104. In particular, forming the openings 110 through the base 108 may expose certain parts of the first portion 112 of the traces 104 through the absorber 106 (e.g., to air). That is, some of the first portion 112 of the traces 104 may be exposed in a similar manner as the second portion 114 of the traces 104. Consequently, the environment, and therefore the environmental properties, at the first portion 112 may be more similar to that at the second portion 114. For instance, as compared to an absorber without openings, the absorber 106 having the openings 110 may have a dielectric constant, a permeability value, and/or an impedance that is more similar to that of air. The similarity between the environmental properties at the first portion 112 and at the second portion 114 may improve integrity of signals propagated along the first portion 112 and the second portion 114. As such, the absorber 106 may sufficiently block signal emission off the traces 104 without causing signal degradation along the traces 104, thereby maintaining desirable signal integrity performances (e.g., signal-to-noise ratio, bit error rate). For instance, the openings 110 may reduce attenuation and/or reflection of signals that otherwise may occur in the absence of the openings (e.g., by using a solid absorber without openings), thereby reducing insertion loss and/or return loss of signals propagated along the traces 104.

FIG. 1B is a side view of an embodiment of the PCB assembly 100. As shown in FIG. 1B, the base 108 of the absorber 106 includes a thickness 150 that is significantly greater than that of the traces 104. Moreover, the absorber 106 is positioned in direct contact with the traces 104 in the illustrated embodiment. For instance, the base 108 may press against the traces 104.

FIG. 1C is a side view of another embodiment of the PCB assembly 100. In the illustrated embodiment, the base 108 is offset from the traces 104 to provide a gap or space 200 (e.g., an air gap) between the traces 104 and the absorber 106. As an example, spacers 202 may abut against the layer 102A and the base 108, and the spacers 202 may extend beyond the traces 104 to offset the base 108 from the traces 104. Thus, the absorber 106 and the traces 104 may not contact one another.

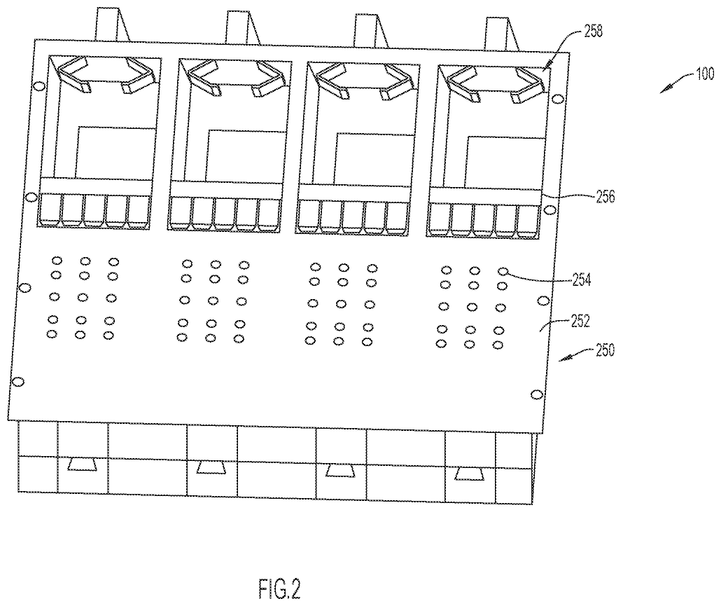

FIG. 2 is a top perspective view of the PCB assembly 100. The illustrated PCB assembly 100 includes an absorber 250 with a base 252, first openings 254 (e.g., relatively smaller openings), and second openings 256 (e.g., relatively larger openings). For example, the base 252 may be positioned over traces (not shown), and the first openings 254 may expose a portion of the traces to reduce a difference between environments at different portions of the traces and improve integrity of signals propagated along the different portions of the traces. Additionally, the second openings 256 may expose interfaces 258 of the PCB assembly 100 for coupling to other components. In this manner, the absorber 250 may include separate openings for improving signal integrity and for enabling coupling of the PCB assembly 100.

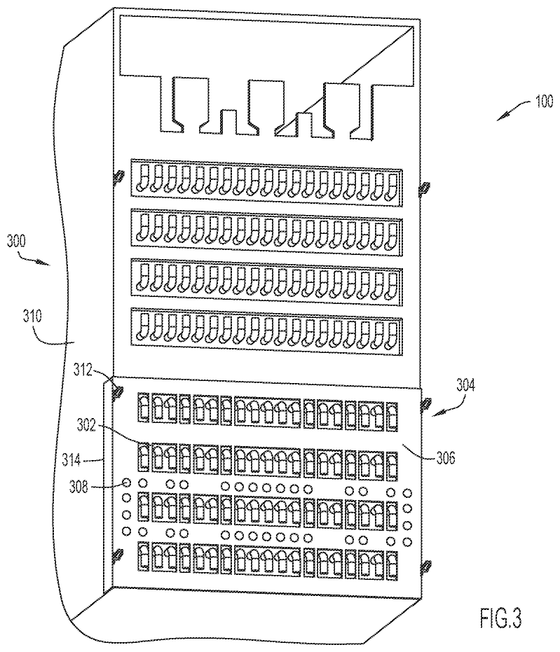

FIG. 3 is a top perspective view of the PCB assembly 100 with an enclosure 300. The enclosure 300 may cover various layers (not shown) of the PCB assembly 100, while exposing traces 302 routed along a layer (e.g., an external layer). An absorber 304 may be positioned over the traces 302 to block signal emission off the traces 302, and the absorber 304 may include a base 306 and openings 308 to expose portions of the traces 302 to reduce a difference between environments at different portions of the traces 302 and improve signal integrity of signals propagated along the different portions of the traces 302.

The absorber 304 may be electrically coupled to ground provided by the enclosure 300. By way of example, the enclosure 300 may include a chassis 310 and chassis mounts 312 extending from the chassis 310. The chassis mounts 312 may be electrically grounded, and the absorber 304 may be positioned against the chassis mounts 312 (e.g., using an interference fit) to couple to the chassis 310 and electrically ground the absorber 304. Additionally or alternatively, the absorber 304 may include a flange 314 used for coupling to the grounded chassis 310, such as by overlapping the flange 314 with the chassis 310 to create an interference fit and/or to enable application of an adhesive and/or a solder to secure the absorber 304 and the chassis 310 to one another. As an example, the flange 314 may be provided by folding over a portion of the base 306.

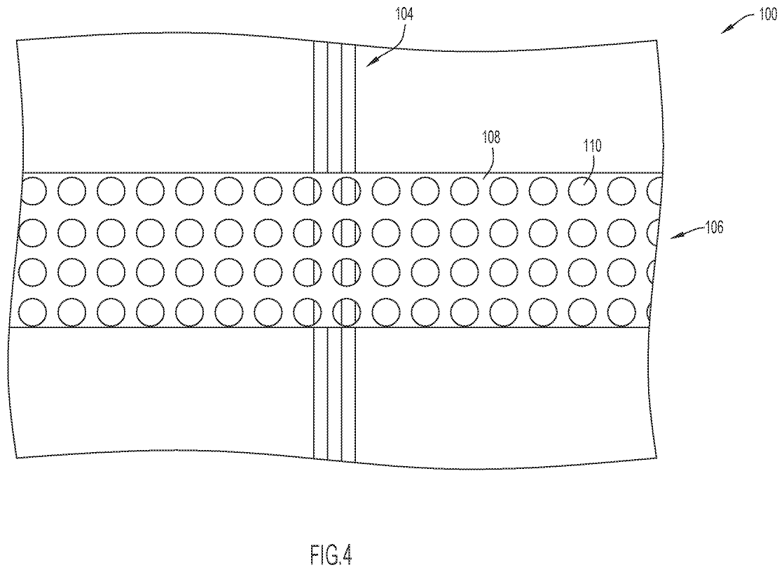

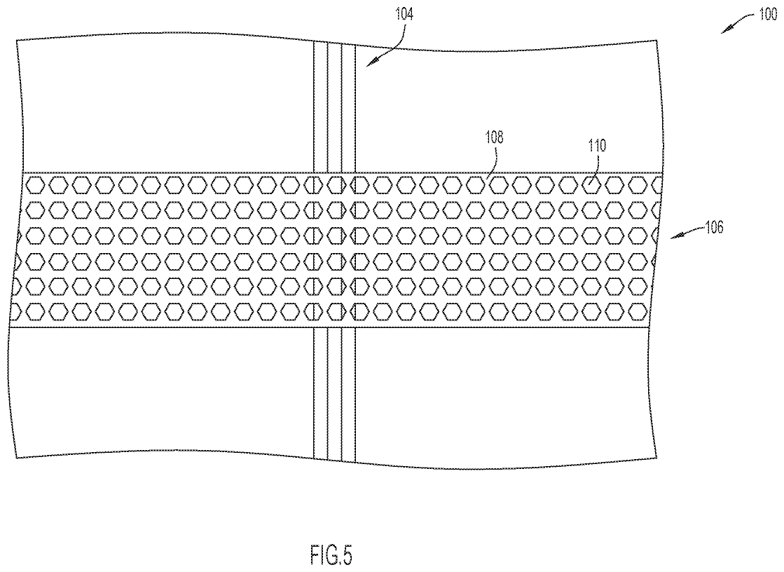

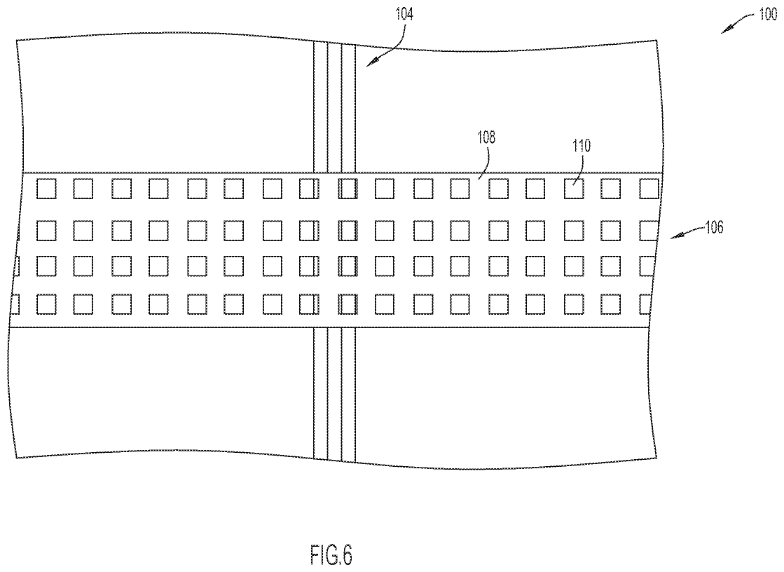

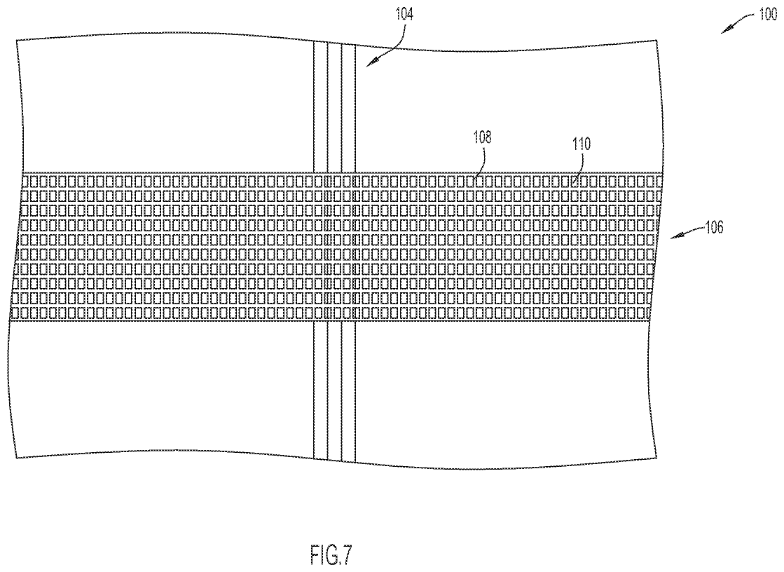

Each of FIGS. 4-7 show a top view of the PCB assembly 100 having different embodiments of the absorber 106 positioned over the traces 104. FIG. 4 shows the absorber 106 as having openings 110 that are circular. FIG. 5 shows the absorber 106 as having openings 110 that are hexagonal. FIG. 6 shows the absorber 106 as having openings 110 that are square. FIG. 7 shows the absorber 106 as having openings 110 that are oblong rectangular. In additional or alternative embodiments, the absorber 106 may have any other suitably shaped openings 110, such as openings 110 that are triangular, pentagonal, trapezoidal, irregularly shaped, and so forth. In each embodiment, some of the openings 110 are positioned in overlap over the traces 104 to expose the traces 104, whereas some of the openings 110 are positioned offset from the traces 104. That is, the absorber 106 may include openings 110 that are both positioned over the traces 104 and that are positioned away from the traces 104. In some implementations, at least one of the openings 110 that are positioned away from the traces 104 may provide access to an interface of the PCB assembly 100.

Although the openings 110 of the absorber 106 in each of FIGS. 4-7 are of substantially the same size and are orderly arranged in multiple rows and columns (e.g., to be equidistant from one another) at least partially spanning the base 108, the openings 110 may be arranged in any other suitable manner in additional or alternative embodiments. By way of example, the openings 110 may be spaced apart from one another by varying distances/pitches and/or directions, have different sizes relative to one another, have different shapes relative to one another, and the like. In an example embodiment, the openings 110 may be arranged based on a parameter associated with the PCB assembly 100, such as a frequency of signals propagated along the traces 104 and/or an environmental property (e.g., a dielectric constant, a permeability value, an impedance) at the traces 104. In another example embodiment, the openings 110 may be randomly formed and arranged. In any of these embodiments, the absorber 106 having the openings 110 may improve performance of the PCB assembly 100, such as in comparison to a PCB assembly without an absorber and/or having an absorber that does not include any openings positioned over traces.

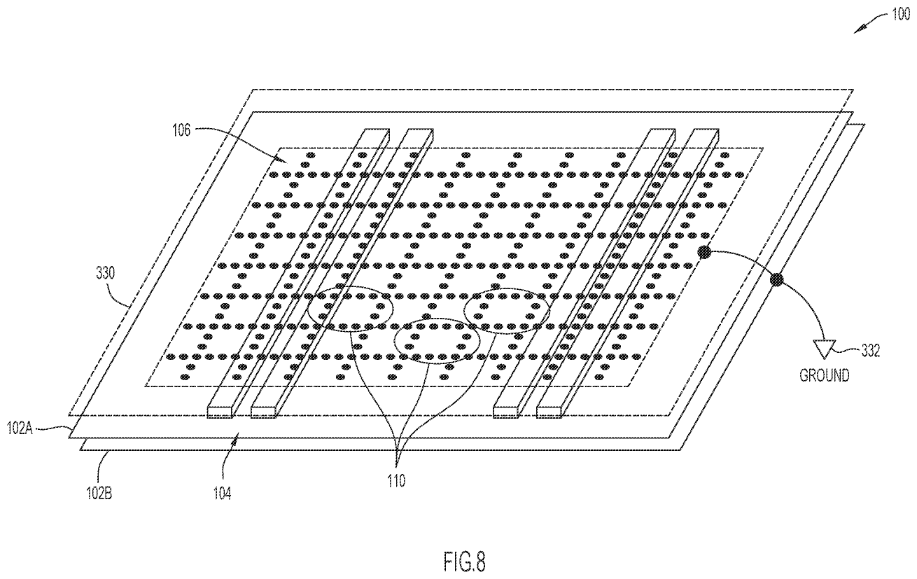

FIG. 8 is a schematic diagram of another embodiment of the PCB assembly 100. The illustrated PCB assembly 100 includes the first layer 102A having the traces 104, along with a second layer 102B (e.g., an intermediate layer). The first layer 102A, and therefore some of the traces 104, may be exposed to air 330. Additionally, the absorber 106 may be positioned over another portion of the traces 104, and the absorber 106 may include openings 110 to reduce an area of shielding over the traces 104 and provide a more homogenous environment surrounding the traces 104 (e.g., to provide environmental properties more similar to that of the air 330), thereby reducing impact on impedance associated with the traces 104. Further, the absorber 106 and the second layer 102B may be electrically coupled to a common ground 332. That is, the second layer 102B may be a ground plane, and the second layer 102B and the absorber 106 may be grounded to one another. Although the second layer 102B is illustrated as being adjacent to the first layer 102A, the second layer 102B electrically coupled to common ground 332 may be positioned in any suitable manner relative to the layer 102A. By way of example, an additional layer (e.g., an additional intermediate layer) may be positioned between the first layer 102A and the second layer 102B.

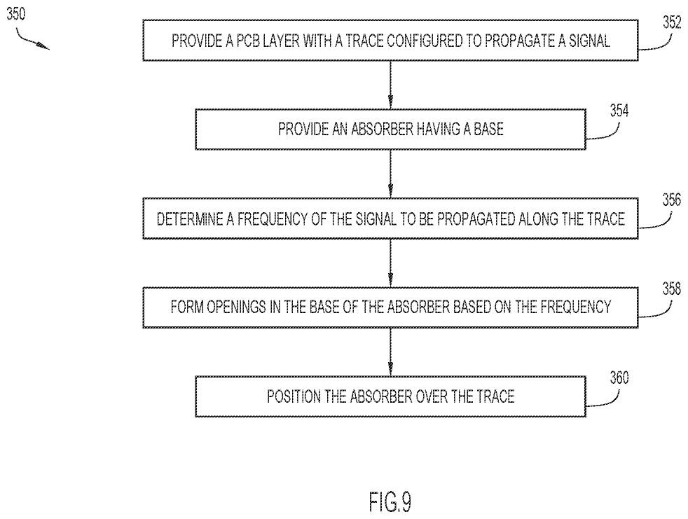

FIG. 9 is a flowchart of a method 350 for manufacturing a PCB assembly, such as any of the PCB assemblies 100 discussed herein. It should be noted that the method 350 may be performed differently in additional or alternative embodiments. For example, an additional operation may be performed, and/or any of the depicted operations may be performed differently, performed in a different order, and/or not performed.

At step 352, a PCB layer with a trace configured to propagate a signal may be provided. The PCB layer may be one of multiple PCB layers, and the PCB layer having the trace may be an external layer, such as a top layer or a bottom layer. The trace may be routed along an outer surface of the PCB layer. At step 354, an absorber having a base may be provided. The base may have a sheet-like structure and may be configured to block signal emission off the trace and/or block electrical interference of the signal propagated along the trace.

At step 356, a frequency (e.g., a frequency range) of the signal to be propagated along the trace of the PCB layer may be determined. The frequency of the signal may indicate a property of the environment at the trace or another parameter associated with signal integrity. The determined frequency of the signal may be used to modify the absorber and achieve desirable signal integrity upon incorporation of the absorber to the PCB layer.

At step 358, openings may be formed in the base of the absorber based on the frequency to tune the absorber for more suitable implementation in the PCB assembly (e.g., to reduce impedance drop along the traces). The openings may reduce or limit discontinuities between environments surrounding different portions of the trace. Thus, the signal propagated along the trace may travel through more homogenous environments to reduce degradation of the signal.

In some embodiments, a quantity of openings may be formed based on the frequency of the signal. By way of example, the openings may be arranged in a plurality of rows and/or columns, and a quantity of openings in each row and/or each column may be established based on the frequency of the signal. Additionally or alternatively, a shape/size of the openings may established be based on the frequency of the signal. In further embodiments, a distance/pitch between the openings may be established based on the frequency of the signal.

At step 360, after the openings have been formed in the base of the absorber, the absorber may be positioned over the trace on the PCB layer. In some embodiments, the base of the absorber may be positioned directly against the trace. In additional or alternative embodiments, the base of the absorber may be offset from the trace. By way of example, a spacer may be positioned on the PCB layer and may extend beyond the trace, and the base of the absorber may be positioned against the space to form a space between the trace and the spacer. In either embodiment, at least some of the openings formed in the base may overlap with the trace to improve signal integrity of the trace.

In certain embodiments, the absorber may be attached to an enclosure or cage in which the PCB layer is positioned. As an example, the absorber may be engaged with chassis mounts of the enclosure. As another example, a portion of the absorber may be folded to provide a flange, and the flange may be engaged with a chassis of the enclosure. In either example, the enclosure may be grounded, and attachment of the absorber to the enclosure may therefore electrically ground the absorber.

In some aspects, the techniques described herein relate to an apparatus including: a layer of a printed circuit board; a trace routed along the layer and configured to transmit a signal; and an absorber positioned over the trace, wherein the absorber is formed of material that absorbs electromagnetic emissions from the trace, the absorber includes a plurality of openings, and an opening of the plurality of openings overlaps with the trace.

In some aspects, the techniques described herein relate to an apparatus, further including a cage enclosing the trace and the absorber.

In some aspects, the techniques described herein relate to an apparatus, wherein the absorber is connected to the cage.

In some aspects, the techniques described herein relate to an apparatus, wherein the absorber includes a flange that extends over and engages with a portion of the cage to connect the absorber to the cage.

In some aspects, the techniques described herein relate to an apparatus, wherein the absorber is in contact with the trace.

In some aspects, the techniques described herein relate to an apparatus, wherein the plurality of openings is arranged in multiple rows and columns at least partially spanning a base of the absorber.

In some aspects, the techniques described herein relate to an apparatus, wherein the opening of the plurality of openings is circular, hexagonal, or rectangular.

In some aspects, the techniques described herein relate to an apparatus including: a printed circuit board having a trace that is configured to transmit a signal; and a perforated sheet positioned over the trace, wherein the perforated sheet includes a hole that exposes the trace through the perforated sheet, and.

In some aspects, the techniques described herein relate to an apparatus, wherein the perforated sheet is offset from the trace to form a gap between the trace and the perforated sheet.

In some aspects, the techniques described herein relate to an apparatus, further including a spacer that offsets the perforated sheet from the trace.

In some aspects, the techniques described herein relate to an apparatus, wherein the printed circuit board includes a layer, wherein the spacer is positioned on the layer, the perforated sheet is positioned on the spacer, and the spacer extends beyond the trace to offset the perforated sheet from the trace.

In some aspects, the techniques described herein relate to an apparatus, further including an enclosure, wherein the trace is positioned in the enclosure, and the perforated sheet is coupled to the enclosure.

In some aspects, the techniques described herein relate to an apparatus, wherein the enclosure includes a chassis and a chassis mount extending from the chassis, and the perforated sheet is engaged with the chassis mount to couple to the enclosure.

In some aspects, the techniques described herein relate to an apparatus, wherein the perforated sheet includes an additional hole offset from the trace.

In some aspects, the techniques described herein relate to an apparatus, wherein the additional hole provides access to an interface of the printed circuit board.

In some aspects, the techniques described herein relate to an apparatus, wherein the perforated sheet is made of material that absorbs electromagnetic radiation from the trace.

In some aspects, the techniques described herein relate to a method including: providing a layer of a printed circuit board, the layer including a trace routed along the layer, wherein the trace is configured to propagate a signal; providing an absorber with a base; determining a frequency of the signal to be propagated along the trace; forming a plurality of openings in the base of the absorber based on the frequency of the signal; and positioning the absorber over the trace.

In some aspects, the techniques described herein relate to a method, wherein the layer of the printed circuit board is positioned in an enclosure, and the method includes coupling the absorber to the enclosure.

In some aspects, the techniques described herein relate to a method, including: folding the base to provide a flange; and positioning the flange in contact with the enclosure to couple the absorber to the enclosure.

In some aspects, the techniques described herein relate to a method, including forming a quantity of the plurality of openings, forming a shape of the plurality of openings, forming a size of the plurality of openings, and/or offsetting openings of the plurality of openings from one another along the base of the absorber based on the frequency of the signal.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

Each example embodiment disclosed herein has been included to present one or more different features. However, all disclosed example embodiments are designed to work together as part of a single larger system or method. This disclosure explicitly envisions compound embodiments that combine multiple previously discussed features in different example embodiments into a single system or method.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

Further, the present disclosure may repeat reference numerals and/or letters in the various examples. This repetition is for the purpose of simplicity and clarity and does not in itself dictate a relationship between the various embodiments and/or configurations discussed. Example embodiments that may be used to implement the features and functionality of this disclosure are described with more particular reference to the accompanying figures above.

Similarly, when used herein, the term “comprises” and its derivations (such as “comprising”, etc.) should not be understood in an excluding sense, that is, these terms should not be interpreted as excluding the possibility that what is described and defined may include further elements, steps, etc. Meanwhile, when used herein, the term “approximately” and terms of its family (such as “approximate”, etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially.”

What is claimed is:

1. An apparatus comprising:
a layer of a printed circuit board;
a trace routed along the layer and configured to transmit a signal; and
an absorber positioned over the trace, wherein the absorber is formed of material that absorbs electromagnetic emissions from the trace, the absorber comprises a plurality of openings, and an opening of the plurality of openings overlaps with the trace.

2. The apparatus of claim 1, further comprising a cage enclosing the trace and the absorber.

3. The apparatus of claim 2, wherein the absorber is connected to the cage.

4. The apparatus of claim 3, wherein the absorber comprises a flange that extends over and engages with a portion of the cage to connect the absorber to the cage.

5. The apparatus of claim 1, wherein the absorber is in contact with the trace.

6. The apparatus of claim 1, wherein the plurality of openings is arranged in multiple rows and columns at least partially spanning a base of the absorber.

7. The apparatus of claim 1, wherein the opening of the plurality of openings is circular, hexagonal, or rectangular.

8. An apparatus comprising:
a printed circuit board having a trace that is configured to transmit a signal; and
a perforated sheet positioned over the trace, wherein the perforated sheet includes a hole that exposes the trace through the perforated sheet, and.

9. The apparatus of claim 8, wherein the perforated sheet is offset from the trace to form a gap between the trace and the perforated sheet.

10. The apparatus of claim 9, further comprising a spacer that offsets the perforated sheet from the trace.

11. The apparatus of claim 10, wherein the printed circuit board includes a layer, wherein the spacer is positioned on the layer, the perforated sheet is positioned on the spacer, and the spacer extends beyond the trace to offset the perforated sheet from the trace.

12. The apparatus of claim 8, further comprising an enclosure, wherein the trace is positioned in the enclosure, and the perforated sheet is coupled to the enclosure.

13. The apparatus of claim 12, wherein the enclosure comprises a chassis and a chassis mount extending from the chassis, and the perforated sheet is engaged with the chassis mount to couple to the enclosure.

14. The apparatus of claim 8, wherein the perforated sheet comprises an additional hole offset from the trace.

15. The apparatus of claim 14, wherein the additional hole provides access to an interface of the printed circuit board.

16. The apparatus of claim 8, wherein the perforated sheet is made of a metal, a resin, a nitrile, a polymer, or any combination thereof.

17. A method comprising:
providing a layer of a printed circuit board, the layer comprising a trace routed along the layer, wherein the trace is configured to propagate a signal;
providing an absorber with a base;
determining a frequency of the signal to be propagated along the trace;
forming a plurality of openings in the base of the absorber based on the frequency of the signal; and
positioning the absorber over the trace.

18. The method of claim 17, wherein the layer of the printed circuit board is positioned in an enclosure, and the method comprises coupling the absorber to the enclosure.

19. The method of claim 18, comprising:
folding the base to provide a flange; and
positioning the flange in contact with the enclosure to couple the absorber to the enclosure.

20. The method of claim 17, comprising forming a quantity of the plurality of openings, forming a shape of the plurality of openings, forming a size of the plurality of openings, and/or offsetting openings of the plurality of openings from one another along the base of the absorber based on the frequency of the signal.
